(19) United States
(12) Patent Application Publication
(10) Pub. No.: US 2010/0214845 A1
(43) Pub. Date: Aug. 26, 2010

(54) NAND MEMORY CELL ARRAY, NAND FLASH MEMORY HAVING NAND MEMORY CELL ARRAY, DATA PROCESSING METHOD FOR NAND FLASH MEMORY

(76) Inventor: Woong Lim Choi, Suwon-si (KR)

Correspondence Address: Jae Y. Park, Kile, Goekjian, Reed & McManus, PLLC, 1200 New Hampshire Ave. NW, Suite 570, Washington, DC, 20036, US

(21) Appl. No.: 12/680,697

(22) PCT Filed: Sep. 10, 2008
(86) PCT No.: PCT/KR08/05339

§ 371 Date: Mar. 29, 2010

(30) Foreign Application Priority Data
Oct. 1, 2007 (KR) 10-2007-0098632

(51) Int. Cl. G11C 16/02; G11C 7/00

(52) U.S. Cl. 365/185.18; 365/189.11

(57) ABSTRACT

A NAND memory cell array which can be programmed in a hot carrier injection scheme, a NAND flash memory having the NAND memory cell array, and a data processing method for the NAND flash memory are provided. The NAND memory cell array includes one select transistor and at least two storage transistors. The NAND memory cell array can be programmed by controlling a bulk bias voltage and a voltage applied to a gate in the hot carrier injection scheme.

### TECHNICAL FIELD

The present invention relates to a flash memory, and more particularly, to a NAND memory cell array capable of being programmed with low current, low voltage, and low power consumption, a NAND flash memory having the NAND memory cell array, and a data processing method for the NAND flash memory.

### BACKGROUND ART

Flash memory architectures can be mainly classified into a NOR flash memory architecture and a NAND flash memory architecture according to array schemes of memory cells disposed between bit lines and a ground line. In the NOR flash memory, the memory cells are disposed in parallel between the bit lines and the ground line. In the NAND flash memory, the memory cells are disposed in series between the bit lines and the ground lines.

In the NOR flash memory, a hot carrier injection scheme is used for programming the memory cell, that is, storing a data in the memory cell, and a Fowler-Nordheim (FN) tunneling scheme is used for erasing the data programmed in the memory cell.

An N-type storage transistor used for storing the data in the NOR memory cell includes five terminals of drain, source, floating gate, control gate, and bulk terminals. When the NOR memory cell constructed with the N-type storage transistors is programmed in the hot carrier injection scheme, a voltage ranging from 4V to 5V is applied to the drain of the N-type storage transistor, a high voltage of about 9V is applied to the control gate, and a ground voltage is applied to the source.

In this case, electrons move along a channel generated between the source and the drain. In the channel, the electrons obtain high kinetic energy due to a strong electric field in a saturation region of the channel. Some of the hot electrons, that is, the electrons having the high kinetic energy due to the strong electric field pass through a potential barrier of a floating gate dielectric between the floating gate and the channel region to be injected into the floating gate. The electrons injected into the floating gate are isolated within the potential barrier under the conditions that there is no external change. As seen from the control gate disposed on the floating gate, the electrons isolated within the floating gate lead to an increase in a threshold voltage of the N-type storage transistor. As a result, the N-type storage transistor is in the programmed state.

The FN tunneling phenomenon observed by Fowler and Nordheim is a physical phenomenon that tunneling current passing through a dielectric material exponentially increases under a high electric field generated in the dielectric material by applying a high voltage to the dielectric material disposed between two electrodes.

As a method of erasing the electrons isolated within the floating gate by using the FN tunneling phenomenon, there are a method of applying a high voltage between a control gate and a bulk and a method of applying a high voltage between the control gate and a source or between the control gate and a drain.

In the method of applying the high voltage between the control gate and the bulk, a voltage of about −9V is applied to the control gate, and a voltage of about +8V is applied to the bulk. Due to the applied voltages, a strong electric field is generated in the dielectric material disposed between the floating gate and the bulk. Due to the applied voltages, the electrons isolated within the floating gate are moved toward the dielectric material contacting the floating gate, and due to the strong electric field generated in the dielectric material, the moving electrons tunnel into the bulk region. When the electrons isolated within the floating gate are erased from the floating gate, the threshold voltage of the N-type storage transistor as seen from the control gate is decreased. The erasing of the isolated electrons from the floating gate denotes an inverse operation of the programming operation.

In the operation of erasing the electrons by applying the high voltage between the control gate and the bulk, no bias voltage is applied to the source or drain diffusion region of the N-type cell MOS transistor. Therefore, although the high voltage is applied so as to erase the isolated electrons from the floating gate, an area of the diffusion region of the N-type storage transistor or a length of gate thereof needs not be affected so much.

In the FN tunneling method of erasing the isolated electrons from the floating gate by applying the high bias voltage between the control gate and the source or between the control gate and the drain, since the high voltage is applied to the source or drain diffusion region, the area of the diffusion region needs to be large. Therefore, there is a problem in that a size of the memory cell is increased.

Conventional cells having select transistor(s) are mainly classified as follows.

1. A 2-transistor cell having one select transistor and one storage transistor

2. A 3-transistor cell having one storage transistor and two select transistors interposing the storage transistor.

3. A NAND cell having a plurality of serially-connected storage transistors and two select transistors interposing the storage transistors.

In a cell array of the aforementioned cells having the select transistors, in order to program or read a selected cell, a current for programming or reading needs to pass through the select transistor or through the select transistor and at least one cell so as to access the corresponding cell. In such a structure, it is difficult to applying a programming method using the conventional hot carrier injection scheme in which a high current of 100 μA or more needs to flow because the high level of current causes a high voltage drop in the to-be-passed devices due to a serial resistance of the to-be-passed devices. For this reason, the FN tunneling programming method in which a high voltage is applied between the control gate and the source or between the control gate and the drain is used to program the cell having the select transistors. In the FN tunneling programming method, substantially no current is consumed. However, as described above, since a high voltage of 14V or more needs to be applied to the source or drain diffusion region, the FN tunneling programming method has a problem of an increase in a size of cell. On the contrary, in the programming method using the hot carrier injection scheme, a relatively low voltage of 5V or less is applied to the drain terminal.

In general, a NAND flash memory includes at least 32 serially-connected storage transistors. In order to access a storage transistor located at an intermediate position among the serially-connected storage transistors, other storage transistors adjacent to the to-be-accessed storage transistor needs to be passed. The storage transistors adjacent to the to-be-accessed storage transistor are referred to as pass transistors. In order to program the NAND cell including the serially-connected storage transistors between the bit line and the ground line by using the hot carrier injection scheme, the drain voltage of about 5V or more applied through the bit line together with a high current of 100 μA or more must be transferred to the to-be-programmed cell. At this time, since voltage drop occurs due to resistances of the turned-on serially-connected storage transistors, very high voltage needs to be applied to the gates of the pass transistors in order to prevent the occurrence of voltage drop. However, since the high gate voltage causes a disturbance phenomenon resulting in a change in a charge storage state of the pass transistors, there is a limitation to increase the gate voltage. For this reason, the hot carrier injection scheme in which high current and voltage need to pass through a plurality of serially-connected storage transistors is difficult to use as a programming method for a conventional NAND cell structure. Therefore, the programming and erasing operation for the NAND flash memory have been performed by using only the FN tunneling scheme.

In addition, the NAND flash memory and the NOR flash memory have significant differences in terms of operating voltage. In general, a maximum operating voltage of the NAND flash memory is about 20V, which is twice larger than a maximum operating voltage (about 10V) of the NOR flash memory. If the operating voltage of an integrated circuit is high, the area of the circuit is proportionally increased, so that the area of chip is also increased. Particularly, as the voltage and current for the programming operation are increased, the length and width of a cell transistor and spaces between cells are proportionally increased, so that the size of cell is increased and the scalability of cell transistor deteriorates. In the NAND flash memory operating in the FN tunneling scheme, the operating current is low, but the operating voltage is too high. On the contrary, in the NOR flash memory operating in the hot carrier injection scheme, the operating voltage is low, but the operating current is too high. And the effective cell size of NAND flash cell array is much smaller than that of NOR flash cell array. Therefore, by applying a low-voltage low-current hot carrier injection scheme to the NAND flash memory, an ideal flash memory can be obtained.

### DISCLOSURE

### Technical Problem

The present invention provides a NAND memory cell array capable of being programmed in a hot carrier injection scheme.

The present invention also provides a data processing method for a NAND flash memory capable of writing a data in a NAND memory cell array by using a hot carrier injection scheme or reading or erasing the data stored in the NAND flash memory cell.

### Technical Solution

According to an aspect of the present invention, there is provided a NAND memory cell array comprising: a select transistor having the one terminal connected to a bit line and a gate terminal applied with a select signal; and a storage device operated in response to a word line, the storage device having the one terminal connected to the other terminal of the select transistor and the other terminal connected to a source line, wherein the storage device includes at least two storage transistors connected in series between the other terminal of the select transistor and the source line, and wherein a gate of each storage transistor is connected to each of the plurality of the word lines respectively, a bulk region thereof is applied with a bulk bias voltage at the time of writing (programming) data, and a floating gate or a single or multiple charge storage layer is disposed between the gate and the bulk.

According to another aspect of the present invention, there is provided a NAND memory cell array comprising a storage device including at least two storage transistors connected in series between a bit line and a source line, wherein, in a case where the storage device includes the two storage transistors, the storage device includes: a first storage transistor having the one terminal connected to the bit line and a gate applied with a first word signal; and a second storage transistor having the one terminal connected to the other terminal of the first storage transistor, the other terminal connected to the source line, and a gate connected to a second word line, wherein, in a case where the storage device includes N storage transistors (N is an integer of 3 or more), the storage device includes: a first storage transistor having the one terminal connected to the bit line and a gate connected to the first word line; an (N−1)-th storage transistor having the one terminal connected to the other terminal of an (N−2)-th storage transistor and a gate applied with a (N−1)-th word signal; and an N-th storage transistor having the one terminal connected to the other terminal of the (N−1)-th storage transistor, the other terminal connected to the source line, and a gate applied with an N-th word signal, and wherein, when a data is written (programmed), bulk regions of all the storage transistors are applied with a bulk bias voltage at the time of programming data, and a floating gate or a single or multiple charge storage dielectric layer is provided between the gate and the bulk.

According to further another aspect of the present invention, there is provided a data processing method for a NAND flash memory having a plurality of memory cell arrays, each memory cell array including a select transistor having the one terminal connected to a bit line and a gate applied with a select signal and at least two storage transistors connected in series between the other terminal of the select transistor and a source line and operated in response to two word line signals and a bulk bias voltage applied to a bulk region, wherein a data is programmed in the NAND flash memory by using hot carriers generated in the bulk region or channel region of the at least two storage transistors by a voltage applied through the bit line, a voltage applied through the source line, and the bulk bias voltage.

According to further still another aspect of the present invention, there is provided a data processing method for a NAND flash memory having a plurality of memory cell arrays, each memory cell array including a select transistor having the one terminal connected to a bit line and a gate applied with a select signal and at least two storage transistors connected in series between the other terminal of the select transistor and a source line and operated in response to at least two word line signals and a bulk bias voltage applied to a bulk region, wherein data is programmed in the NAND flash memory by using hot carriers generated in the bulk region or channel region of the at least two storage transistors by a voltage applied through the bit line, a voltage applied through the source line, and the bulk bias voltage, and wherein the data is programmed by changing a voltage level of a word line signal applied to a gate of a storage transistor in which the data is to be programmed among the at least two storage transistors.

### ADVANTAGEOUS EFFECTS

In the NAND memory cell array capable of processing the data with low current and low voltage according to the present invention, one select transistor and at least two storage transistors are provided. According to the present invention, the hot carrier injection scheme is used for the NAND memory cell array, so that it is possible to increase a programming (writing) speed up to that of the NOR memory cell array and to implement low power operation. Accordingly, a performance of a parallel programming process can be improved up to that of a conventional NAND flash memory, and a writing rate per unit time (data writing throughput) can be increased over that of the conventional NAND flash memory. In addition, since the number of storage transistors can be reduced less than that of the conventional NAND flash memory, the time taken to read the data written in the NAND memory cell array can be reduced, so that the NAND memory cell array can be used as a storage device for storing and executing program codes.

According to the present invention, since there is no select transistor provided to the source line, an effective size of cell can be maintained to be small while the number of the serially-connected storage transistors is reduced. In addition, since the operating voltage is lower than that of the conventional NAND flash memory, it is possible to reduce the size of cell and to improve cell scalability.

It should be noted that the operating conditions determining the size of cell in the NAND flash memory are the only programming (writing) conditions. In the erasing operation, since the bias voltages are applied in a unit of a cell block, the bias voltages are not directly related to the size of unit cell. In addition, in the reading operation, the drain voltage and the gate voltage are much lower than those of the programming operation, so that the drain voltage and the gate voltage do not definitely influence the size of cell.

Conventionally, the NOR flash memory with a high reading speed is used for storing the program codes, and the NAND flash memory with high writing speed is used for storing general data. Since the conventional NAND flash memory has too long time taken to read the data, the conventional NAND flash memory cannot be used for executing the codes. However, since the NAND memory cell array according to the present invention has high writing and reading speeds, the NAND memory cell array can be used for storing and executing the codes. In addition, according to the present invention, since the data processing is performed with low current and low voltage, the size of cell, the area of circuit, and the size of chip can be reduced in comparison with the conventional flash memory.

In the NAND memory cell array according to the present invention, there is no select transistor or only one select transistor, and the programming operation is performed by using the low power hot carrier injection scheme. Accordingly, the following advantages can be obtained.

1) In the programming operation, the operating voltage can be lowered. In the conventional FN tunneling scheme, the voltage applied to the gate of cell or the word line is about 18V, and the voltage generated in the diffusion region of unselected NAND string is about 7V. However, in the NAND memory cell array according to the present invention, since the hot carrier injection scheme is used, the voltage applied to the gate of cell or the word line is about 9V or less, and the voltage applied to the diffusion region is about 4V or less.

2) Since the memory cell is programmed by increasing gradually the gate voltage from a low voltage under a bulk bias voltage, the memory cell can be programmed with a low current ranging from tens of nano amperes to several micro amperes.

3) In the NAND memory cell array according to the present invention, the byte programming speed can be increased up to that of the NOR memory cell array, in addition, a large number of cells can be simultaneously programmed by using the low current characteristics. Therefore, the high-speed data transfer can be implemented in the NAND memory cell array.

4) In addition, since a select transistor is provided to the cell, there is no problem of excessive erasing. Therefore, the erasing speed can be increased as high as that of the conventional NAND memory cell array.

5) The number of cells in a cell string of the NAND memory cell array can be reduced smaller than that of the conventional NAND memory cell array, so that it is possible to increase the reading speed up to the level of the NOR memory cell array and to improve the data reliability up to the level of the NOR memory cell array. In this case, since there is no source select transistor, a decrease in the number of cells in the cell string reduces or compensates for the increase in the effective size of cell.

6) Since a select transistor is provided, it is possible to prevent the conventional problems of the NOR memory cell array such as excessive erasing, bit line disturbance, and current leakage of the bit line.

7) Since the NAND memory cell array is formed in a NAND string type, it is possible to greatly reduce the effective size of cell in comparison with the conventional NOR memory cell array.

8) Since the NAND flash memory can be implemented in the hot carrier injection scheme with low current and low voltage, areas of peripheral circuits can be greatly reduced.

9) The advantages of the conventional NOR memory cell array such as the high-speed reading operation, the high-speed byte writing operation, and the high data reliability and the advantages of the conventional NAND memory cell array such as the high-speed data transfer and the high-speed erasing can be simultaneously implemented.

10) In addition, the cell size can be reduced to be much lower than that of the conventional NOR memory cell array, and the areas of the peripheral circuits with respect to the NAND flash memory cell can be greatly reduced, so that the size of chip can be reduced. Accordingly, it is possible to greatly improve the productivity of the non-volatile memory chip.

11) In the conventional NAND flash memory, since the operating voltage is too high, a high voltage circuit, a word line driver, a bit line decoding circuit, and a high voltage transfer circuit have large areas. Therefore, when the density of the NAND flash memory is lowered in a given process generation, the ratio of a cell area to the whole chip area is greatly decreased. In other words, in the high density products, the NAND flash memory has a productivity higher than that of the NOR flash memory. However, in the low density products, the NAND flash memory has a productivity lower than that of the NOR flash memory. On the other hand, in the NOR flash memory, the cell size is large. Therefore, in the high density products, the NOR memory has a productivity lower than that of the NAND flash memory.

The memory cell size according to the present invention can be reduced as small as that of the NAND flash memory and operates with a voltage as low as that of the NOR flash memory, so that it is possible to obtain advantages of reducing the size of cell and the areas of circuits. Therefore, a chip employing the memory cell array and the peripheral circuits according to the present invention has a high competitiveness in both high and low density flash memory products.

The flash memory products employing the memory cell array according to the present invention has combinational characteristics of the NOR and NAND flash memories. In addition, the flash memory products have a high competitiveness in terms of the size of chip. Due to the advantages, the flash memory products are suitable for high-end as well as low-end mobile communication systems.

While the present invention has been particularly shown and described with reference to exemplary embodiments thereof, it will be understood by those skilled in the art that various changes in form and details may be made therein without departing from the spirit and scope of the invention as defined by the appended claims. The exemplary embodiments should be considered in descriptive sense only and not for purposes of limitation. Therefore, the scope of the invention is defined not by the detailed description of the invention but by the appended claims, and all differences within the scope will be construed as being included in the present invention.

### DESCRIPTION OF DRAWINGS

FIG. 1 is a cross-sectional view illustrating a NAND memory cell array according to a first embodiment of the present invention;

FIG. 2 is a cross-sectional view illustrating a NAND memory cell array according to a second embodiment of the present invention;

FIG. 3 is a cross-sectional view illustrating a NAND memory cell array according to a third embodiment of the present invention;

FIG. 4 is a cross-sectional view illustrating a NAND memory cell array according to a fourth embodiment of the present invention;

FIG. 5 is a view illustrating connections between bit and source lines and the NAND memory cell arrays shown in FIGS. 1 to 3;

FIG. 6 is a schematic view illustrating connections between bit and source lines and the NAND memory cell array shown in FIG. 4;

FIG. 7 is a schematic view illustrating one NAND memory cell array constituting the NAND flash memory shown in FIG. 5;

FIG. 8 is a table illustrating bias conditions for data storing, data reading, or data erasing in the NAND memory cell array shown in FIG. 7;

FIG. 9 is a schematic view illustrating one NAND memory cell array constituting the NAND flash memory shown in FIG. 6; and

FIG. 10 is a table illustrating bias conditions for data storing, data reading, or data erasing in the NAND memory cell array shown in FIG. 9.

### BEST MODE

Hereinafter, exemplary embodiments of the present invention will be described in detail with reference to the accompanying drawings.

Firstly, principal idea of the present invention will be described.

In a NAND flash memory according to the present invention, a drain select transistor is disposed between a bit line and the one terminal of one of serially-connected storage transistors, and a source line is directly connected to the other terminal of the storage transistors. Accordingly, a hot carrier injection scheme can be used to implement a NAND flash memory having only one select transistor under the following bias conditions.

In a conventional NAND flash memory, since FN tunneling scheme is used to write a data, a NAND flash memory structure having a drain select transistor connected to a bit line and a source select transistor connected to a source line has been proposed. However, according to the present invention, a NAND flash memory capable of writing a data by using a hot carrier injection scheme together with a low current and low voltage method for the NAND flash memory is proposed.

The conventional NAND flash memory cell array generally has more than or equal to 32 serially-connected storage transistors. Since the number of serially-connected storage transistors is large, the sense current for reading data stored in a cell is reduced and very small due to a large serial resistance, so that data reading speed (random access speed) is lowered, and data reliability may be deteriorated. Due to too much time taken to read the data, the conventional NAND flash memory is not suitable for storing and executing program codes. A way to improve the reading speed is to reduce the number of serially-connected storage transistors, for instance, down to less than sixteen. However, for a conventional NAND flash array, reducing the number of serially-connected storage transistors increases too much the effective cell size due to the large size of two select transistors. Consequently, the NAND flash memory will not be competitive any more in productivity. The silicon area for the select transistors to occupy is very large for a conventional NAND flash memory because of the high level of operating voltages during programming and erasing.

However, in the NAND flash memory and the data processing method for the NAND flash memory according to the present invention, the number of serially-connected storage transistors can be reduced without significant increase of effective cell size because the proposed NAND memory cell array has only one select transistor and its operating voltages are much lower than those of the conventional NAND cell array. Reduction of the number of serially-connected storage transistors increases the sense current and the time taken to read data is reduced. Accordingly, the read speed and data reliability can be improved, and the NAND flash memory can be suitably used for storing and executing program codes while maintaining the advantage of small cell size of NAND memory array.

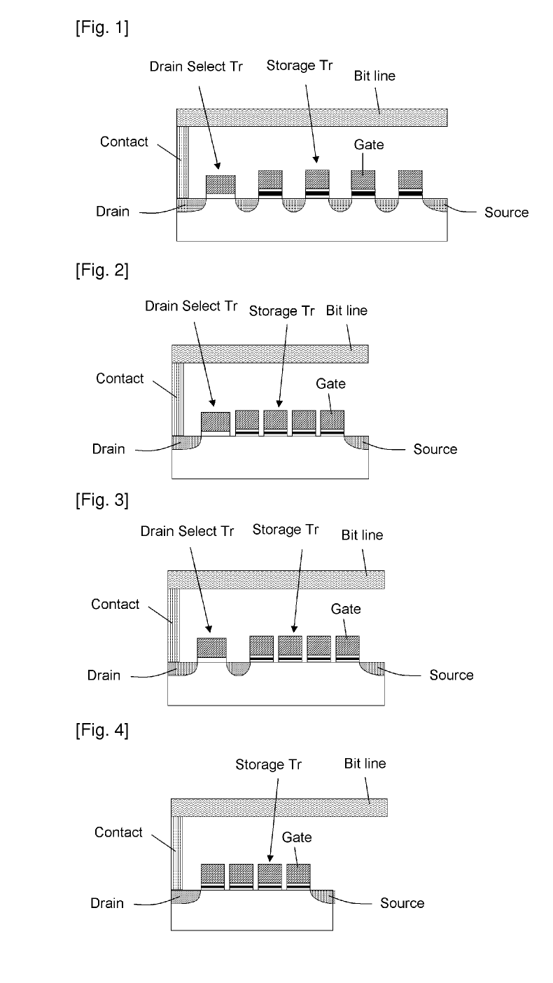

FIG. 1 is a cross-sectional view illustrating a NAND memory cell array according to a first embodiment of the present invention.

Referring to FIG. 1, in the NAND memory cell array, one drain select transistor Select Tr and four storage transistors Storage Tr are connected in series. The four storage transistors Storage Tr hatched by doted lines are referred to as first to fourth storage transistors in the rightward direction. Although the four storage transistors are shown in FIG. 1 for the convenience of description, the NAND memory cell array may include less than or more than four storage transistors.

The one terminal, that is, a drain of the drain select transistor Select Tr is connected through a contact to a bit line Bit line, and a gate thereof is applied with a select signal (not shown). The one terminal of the first storage transistor is connected to the other terminal of the drain select transistor Select Tr, and a gate thereof is connected to a first word line (not shown). The one terminal of the second storage transistor is connected to the other terminal of the first storage transistor, and a gate thereof is connected to a second word line (not shown). The one terminal of the third storage transistor is connected to the other terminal of the second storage transistor, and a gate thereof is connected to a third word line (not shown). The one terminal of the fourth storage transistor is connected to the other terminal of the third storage transistor, and a gate thereof is connected to a fourth word line (not shown).

Although not shown in detail in FIG. 1, a common bulk region (substrate) of the four storage transistors Storage Tr is applied with a bulk bias voltage. In addition, a bulk region of the select transistor Select Tr may also be applied with the same bulk bias voltage. Alternatively, the bulk region of the select transistor may be separated from the common bulk region of the four storage transistors. Particularly, according to the present invention, in case of NMOS transistors, a negative bulk bias voltage may be applied to the four storage transistors Storage Tr at the time of writing (programming) a data in the NAND memory cell array.

The drain select transistors Select Tr and the four storage transistors Storage Tr are connected in series through impurity-implanted diffusion regions, that is, source and drain regions of the cell. In addition, in each of the four storage transistors Storage Tr, a charge storage floating gate or charge storage dielectric layer is provided between a gate terminal Gate and the bulk region.

The charge storage dielectric layer is constructed by laminating at least one oxide layer and at least one nitride layer or by laminating a tetrahedral amorphous carbon layer and at least one oxide layer. The charge storage dielectric layer may be, for example, an oxide-nitride (ON) layer, an oxide-nitride-oxide (ONO) layer, or a tetrahedral amorphous carbon-oxide (TAC-O) layer. And any other types of storage materials, such as ferroelectric materials, magnetic materials, etc., may also be incorporated between the gate and bulk. Although not shown in the figure, the gate dielectric layer of the select transistor Select Tr may be constructed with a single oxide layer or the aforementioned charge storage dielectric layer. The gate dielectric layer of the select transistor Select Tr may also be constructed with the same layer as or different layer to that of the storage transistors in terms of material, structure and thickness.

In the following description, although not specifically described, all the storage transistors may include the floating gate or the charge storage dielectric layer. In addition, the bulk regions of all the storage transistors Storage Tr and the select transistors Select Tr are applied with the bulk bias voltages.

Similarly to FIG. 1, in the following figures, the select signals and word line signals connected to the gates may be omitted for simplification of the drawings. In the following figures, the connections among the gates, the select signals, and the word line signals can be easily derived from the description with reference to FIG. 1.

FIG. 2 is a cross-sectional view illustrating a NAND memory cell array according to a second embodiment of the present invention.

Referring to FIG. 2, the NAND memory cell array according to the second embodiment has the same structure as that of the NAND memory cell array according to the first embodiment shown in FIG. 1 except that there is no diffusion region excluding a diffusion region Drain constituting the one terminal of a drain select transistor Select Tr connected to the bit line Bit line and a diffusion region Source constituting the one terminal of a fourth storage transistor connected to the source line VS (not shown). The four transistors Storage Tr hatched by doted lines are referred to as first to fourth storage transistors in the rightward direction.

FIG. 3 is a cross-sectional view illustrating a NAND memory cell array according to a third embodiment of the present invention.

Referring to FIG. 3, the NAND memory cell array according to the third embodiment has the same structure as that of the NAND memory cell array according to the second embodiment shown in FIG. 2 except that the select transistor Select Tr and the first storage transistor are connected through an additional diffusion region. The four transistors Storage Tr hatched by doted lines are referred to as first to fourth storage transistors in the rightward direction.

As shown in FIGS. 1 to 3, the present invention proposes NAND memory cell arrays using the select transistor Select Tr located at the drain side. Alternatively, the present invention also proposes a NAND memory cell array using no select transistor.

FIG. 4 is a cross-sectional view illustrating a NAND memory cell array according to a fourth embodiment of the present invention.

Referring to FIG. 4, in the NAND memory cell array, there is no select transistor and no diffusion region between storage transistors. The one terminal of one of the storage transistors Storage Tr is directly connected to a bit line Bit line, and the one terminal of the opposite one among the storage transistors is connected to the source.

The NAND memory cell array shown in FIGS. 1 to 4 can be programmed in a hot carrier injection scheme by applying a fixed voltage or a variable voltage to a bulk. The programming of the NAND memory cell array will be described later.

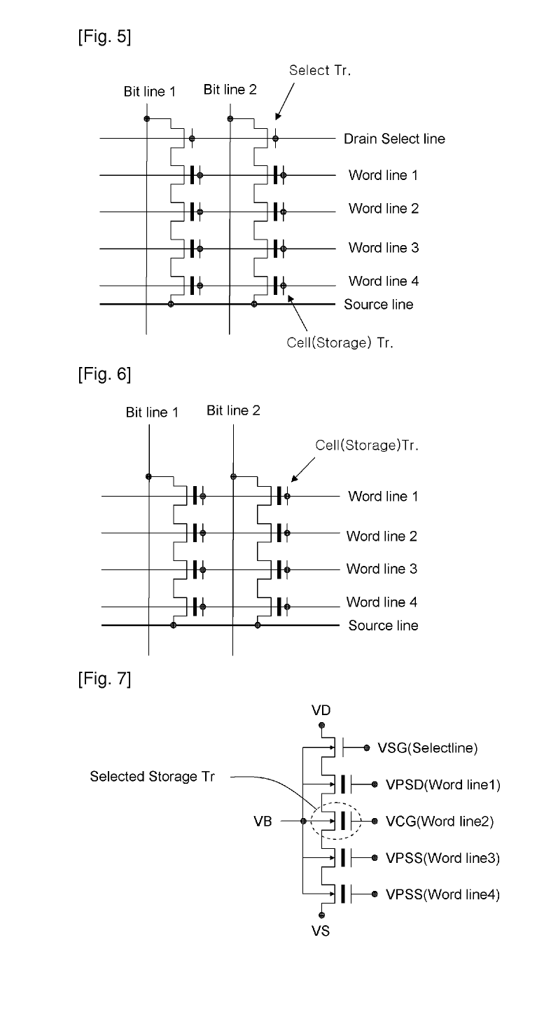

FIG. 5 is a view illustrating connections between the bit and source lines and the NAND memory cell arrays shown in FIGS. 1 to 3.

Referring to FIG. 5, unlike a conventional NAND memory cell array where the select transistor connected to the source line is used, in the NAND memory cell array according to the present invention, the only select transistor Select Tr directly connected to the bit line Bit line 1 or Bit line 2 is used. In addition, unlike the conventional NAND flash memory, NAND memory cell array according to the present invention can be programmed in the hot carrier injection scheme by applying the bulk bias voltage (not shown) to the storage transistors and/or applying a variable gate voltage to a selected storage transistor, which will be described later.

A select signal is applied to the gate of the select transistor Select Tr through a select signal line Drain Select line, and word signals are applied to the gates of the four storage transistors through word lines Word line 1 to Word line 4.

FIG. 6 is a schematic view illustrating connections between the bit and source lines and the NAND memory cell array shown in FIG. 4.

Referring to FIG. 6, the storage transistor Storage Tr is directly connected to the bit line Bit line 1 or Bit line 2. Unlike the conventional NAND flash memory, the NAND memory cell array shown in FIG. 6 can also be programmed in the hot carrier injection scheme by applying the bulk bias voltage to the storage transistors and/or applying a variable gate voltage to a selected storage transistor. The word signals are applied to the gates of the four storage transistors through the word lines Word line 1 to Word line 4.

FIG. 7 is a schematic view illustrating one NAND memory cell array constituting the NAND flash memory shown in FIG. 5.

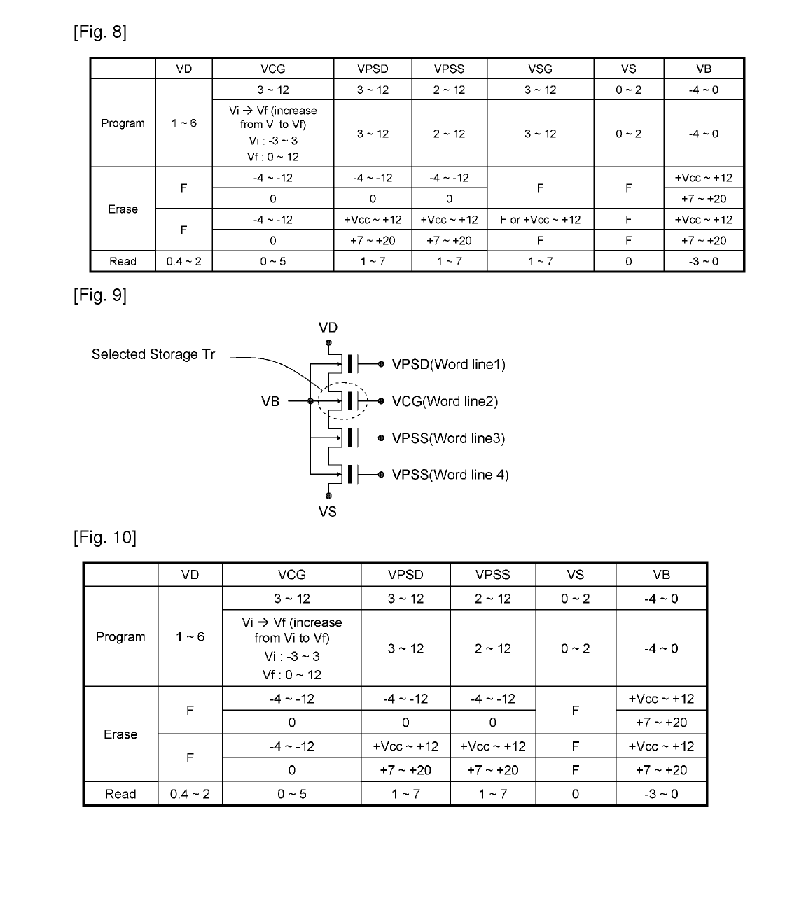

FIG. 8 is a table illustrating bias conditions for data storing (programming), data reading, or data erasing in the NAND memory cell array shown in FIG. 7.

Referring to FIG. 7, the NAND flash memory includes one select transistor Select Tr and four storage transistors Storage Tr. The four storage transistors are exemplified for the convenience of description, but the NAND flash memory may include less than or more than four storage transistors.

A drain voltage VD is applied to the one terminal of the select transistor through the bit line Bit line, and a select signal VSG is applied to the gate thereof through the select signal line. The one terminal of the first storage transistor is connected to the other terminal of the select transistor Select Tr, and a first word voltage VPSD is applied to the gate of the first storage transistor through a first word line Word line 1. The one terminal of the second storage transistor is connected to the other terminal of the first storage transistor, and a second word voltage VCG is applied to the gate of the second storage transistor through a second word line Word line 2. The one terminal of the third storage transistor is connected to the other terminal of the second storage transistors, and a third word voltage VPSS is applied to the gate of the third storage transistor through a third word line Word line 3. The one terminal of the fourth storage transistor is connected to the other terminal of the third storage transistor, and a fourth word voltage VPSS is applied to the gate of the fourth storage transistor through a fourth word line Word line 4. Now, a data storing operation, a data reading operation, and a data erasing operation for the selected storage transistor indicated a doted ellipse will be described.

Bias conditions for bias voltages to be applied to the gate and bulk of each transistor so as to store (program), read, or erase a date of the transistor are listed in a table shown in FIG. 8. More specifically, data of the storage transistor can be stored, read, or erased by adjusting the voltage level VD of the bit line, the voltage levels VCG, VPSD, and VPSS applied to the first to fourth word lines, and the voltage level VS of the source line.

In the later description, an NMOS transistor is exemplified. However, the same description can be applied to a PMOS transistor.

Firstly, a case of writing (programming) data in the second storage transistor among the four storage transistors is described.

When the data is stored in the second storage transistor, high energy charges generated in the channel or bulk regions of the second storage transistor need to be stored by a hot carrier injection scheme in the floating gate or the charge storage dielectric layer of the second storage transistor. In order to make it possible, a high voltage needs to be applied between the drain and the source of the second storage transistor which the data is to be stored in, and voltage drops between the drain and the source of each of the remaining storage transistors need to be as low as possible. A voltage drop in the select transistor needs also to be as low as possible. Under the bias conditions, the unselected remaining storage transistors serve as pass transistors which can pass voltage and current. In this way, a high electric field is generated between the drain and the source of the second storage transistor which the data is to be stored in, so that hot carriers (high-energy charges) are generated due to the high electric field. The hot carriers are attracted and captured by the floating gate or the charge storage dielectric layer due to a vertical electric field which is generated between the gate and the bulk region by the voltage applied to the gate of the second storage transistor.

In order to form such bias conditions, the gate of the selected second storage transistor is applied with a voltage lower than that of the remaining pass storage transistors. If the gate voltage is low, a channel resistance of the transistor is increased, so that a voltage drop between the drain and the source of the transistor can be increased. Suitable voltage levels to be applied to the gates may be adjusted according to physical properties of the storage transistor. The gate voltage of the select transistor needs also to be high enough for the drain voltage VD to be passed through the select transistor without significant voltage drop.

According to the table of FIG. 8, a voltage level VCG of a signal applied to the gate of the selected second storage transistor is set to be lower than voltage levels VPSD and VPSS of signals applied to the gates of the remaining storage transistors.

The voltage level VPSD of the first storage transistor disposed at the position toward the bit line from the selected storage transistor may be set to be different from the voltage levels VPSS of the third and fourth storage transistors at the positions toward the source line from the selected storage transistor. The voltage levels of the signals applied to the gates of the remaining unselected storage transistors need to be suitably adjusted according to the drain voltage and physical properties of the storage transistors. Referring to FIG. 8, the voltage level VPSD of the signal applied to the gate of the first storage transistor is in a range of about 3V to 12V, and the voltage levels VPSS of the signals applied to the gates of the third and fourth storage transistors are in a range of about 2V to 12V.

When the data is to be stored (programmed) in the second storage transistor, the voltage level VCG of the signal applied to the gate of the second storage transistor may be in a range of about −3V to 12V. However, during the programming operation, the voltage may be gradually increased from a low voltage level to a high voltage level so as to program the second storage transistor. For example, in an initial stage of the programming operation, the voltage is set to a suitable voltage level in a range of −3V to 3V, and after that, the voltage is gradually increased up to a suitable voltage level in a range of 0V to 12V so as to program the second storage transistor. In this case, the voltage applied to the gate may be increased stepwise, linearly, or in other manners. In addition, an increasing rate of the gate voltage VCG may be adjusted according to target values of a programming rate and an operating current. For example, in case of using the step signal, performance and power consumption may be optimized by adjusting a voltage difference between voltage steps and a time interval, that is, a pulse width between the voltage steps.

Generally, as the increasing rate of the gate voltage VCG is increased, the programming rate is increased, and the operating current is also increased. If the operating current is increased over a predetermined value, the programming rate may be decreased. Therefore, suitable conditions are selected according to physical properties of the storage transistor and specifications of product.

In an alternative example, the programming is coarsely performed at a high speed up to a predetermined threshold voltage, and after that, the programming operation is finely performed at a low speed up to a target threshold voltage.

The programming method of the present invention can also be useful for multi-level programming because the threshold voltage can be precisely programmed by controlling the increasing rate of the gate voltage VCG.

In this manner, if the voltage level of the signal applied to the gate of the storage transistor in which a data is to be stored is gradually increased from a low level to a high level in the programming operation, the hot carrier injection scheme can be easily used for the NAND memory cell array. Generally, in the programming operation of increasing gradually the voltage level of the signal applied to the gate from a low level to a high level, the operating current can be maintained in a low level, down to less than a microampere.

As an example, in the state that a voltage level of a signal applied to a gate of an arbitrary storage transistor in which a data is stored is maintained to be a constant value, the hot carrier injection programming operation is performed. In this case, as the programming operation proceeds, the threshold voltage is increased, so that the programming efficiency is decreased. Accordingly, the threshold voltage is converged to a certain value. Therefore, if the voltage level of the signal applied to the gate of the storage transistor is set to be a low value at the initial stage of the programming operation, the threshold voltage can be converged to a value lower than a target value. Accordingly, if the voltage level of the signal applied to the gate is increased after a suitable time (pulse width) from the initial stage of the programming operation, the programming rate can be increased again, so that the threshold voltage can be increased up to a higher value.

The programming operation can also be explained in terms of programming current. In the state that the voltage level of the signal applied to the gate of the storage transistor is maintained to be a constant value, the programming operation is performed. In this case, as the programming operation proceeds, the threshold value is increased, so that the operating current for the programming operation is gradually decreased. At this time, if the voltage of the signal applied to the gate is increased again, the current is also increased. After that, as the programming operation proceeds, the current is gradually decreased. In this manner, the voltage level of the signal applied to the gate is increased stepwise in the programming operation, so that the peak programming current can be controlled to a low value. In addition, the proposed programming operation can be performed with a relatively low maximum gate voltage of the selected storage transistor because the voltage difference between the gate voltage and the threshold voltage can be controlled to a very low value. The actual values of the voltage difference and the peak current may be determined by the physical properties of the storage transistor and the specifications of target product design.

In the NAND memory cell array, the aforementioned gate voltage changing scheme can be used for the hot carrier injection programming operation with low voltage and low current.

The programming efficiency of the hot carrier injection scheme is determined according to an amount of the generated hot carriers and an injection efficiency of the hot carriers transferred to the storage device. The aforementioned gate voltage changing scheme is a method of reducing the operating current. Since the operating current is reduced, a transfer efficiency of the drain voltage through the serially-connected storage transistors can be increased, so that the programming efficiency can be improved.

Now, a method of increasing a generation rate of the hot carriers will be described.

In a transistor structure, if a drain voltage is increased, the number of hot carriers is increased. However, due to the increase in the drain voltage, the transistor may be in the breakdown region, then a large amount of leakage current is generated and an operating current is also increased. In addition, in order to supply the high voltage and current, an area of a high voltage generating circuit and sizes of transistors along the path of supplying the drain voltage are increased. If the drain voltage and the current are increased, sizes of the cell storage transistors in the NAND memory cell array or the voltage levels of signals applied to the gate thereof need to be increased. Therefore, the cell scalability is also deteriorated.

In order to reduce areas of cells and circuits and improve the cell scalability, it is necessary to reduce the drain voltage and increase the generation rate of the hot carriers. The reduction of the drain voltage and the increase in the generation rate of the hot carriers can be implemented by applying a bulk bias, that is, a back bias to the substrate in the programming operation. The hot carrier injection programming operation is performed by applying voltages to the drain and the gate in the state that a minus bulk bias is applied to the substrate. Therefore, the generation rate of the hot carriers in the channel and the substrate, so that the programming efficiency can be greatly increased. Namely, a ratio of an actual programming current (gate current) to the drain current can be greatly increased.

The programming efficiency is defined as a ratio of a gate current flowing through the storage to the drain current. Therefore, if the programming efficiency is high, the drain current required for obtaining the same programming characteristics is low. In addition, if the bulk bias applying method is used, the drain voltage required for the same programming characteristics can be greatly reduced. Therefore, if the bulk bias method is used for the NAND memory cell array, the hot carrier injection scheme can be implemented with low current and low voltage. Referring to FIG. 8, the bulk bias voltage applied to the bulk is in a range of about −4V to 0V.

In addition, if the bulk bias method is used for the NAND memory cell array, the punch-through and snap-back phenomena can be minimized or eliminated, which greatly improves the scalability of the flash memory cell for a deep sub-micrometer technology.

If the gate voltage changing method and the bulk bias applying method are simultaneously used for the NAND memory cell array, the high-speed low-current low-voltage hot carrier injection programming operation can be more effectively performed.

Unlike the conventional method, the present invention has an advantage in that the hot carrier injection programming operation can be performed with low current and low voltage.

The aforementioned data programming (storing) operation for the memory cell is described with reference to FIG. 8. The data reading operation or the data erasing operation for the storage transistor can be easily performed by using the suitable bias conditions listed in the table of FIG. 8. Therefore, detailed description of the data reading operation and the data erasing operation is omitted. In the data erasing operation, although a high voltage of 20V may be used in a single polarity scheme of the NAND flash memory, a reduced maximum absolute voltage of about 10V or less can be advantageously used in a dual polarity scheme of the NOR flash memory so as to more effectively use the low voltage writing (programming) operation according to the present invention.

FIG. 9 is a schematic view illustrating one NAND memory cell array constituting the NAND flash memory shown in FIG. 6.

FIG. 10 is a table illustrating bias conditions for data storing, data reading, or data erasing in the NAND memory cell array shown in FIG. 9.

Referring to FIG. 9, the one terminal of the first storage transistor is directly connected to the bit line VD, and the gate thereof is applied with the first word voltage VPSD through the first word line Word line 1. The one terminal of the second storage transistor is connected to the other terminal of the first storage transistor, and the gate thereof is applied with the second word voltage VCG through the second word line Word line 2. The one terminal of the third storage transistor is connected to the other terminal of the second storage transistor, and the gate thereof is applied with the third word voltage VPSS through the third word line Word line 3. The one terminal of the fourth storage transistor is connected to the other terminal of the third storage transistor, and the other terminal thereof is connected to the source line VS, and the gate thereof is applied with the fourth word voltage VPSS through the word line Word line 4.

The NAND memory cell array shown in FIG. 9 is different from the NAND memory cell array shown in FIG. 7 in that the select transistor Select Tr is not provided.

Referring to the table of FIG. 10, a voltage level VD applied to the bit line, voltage levels VCG, VPSD, and VPSS applied to the first to fourth word lines, a voltage level VS applied to the source line, and a bulk bias voltage VB required for the data programming (storing), reading, and erasing operations of the memory cell are listed.

For the data writing operation for the second storage transistor Selected Tr indicated by a doted ellipse among the four storage transistors, the voltage level VCG of the signal applied to the gate of the second storage transistor, the voltage level VPSD of the signal applied to the first storage transistor, and the voltage level VPSS of the signal applied to the gate of the fourth storage transistor are listed in the table of FIG. 10.

The bias voltage applying method, the bias conditions, and the programming efficiency are described above with reference to FIGS. 7 and 8.

Since description of FIGS. 9 and 10 can be easily derived from the description of FIG. 8, the detailed description of FIGS. 9 and 10 is omitted.

In a conventional NAND memory cell array, two select transistors are provided to one at the bit line and another at the source line in each NAND cell string. The select transistor provided to the source line is required for the tunneling programming scheme. However, in the hot carrier injection scheme according to the present invention, the select transistor provided to the source line is unnecessary, so that the effective size of a unit cell can be reduced. When the two select transistors are used as in a conventional NAND memory cell array, voltage drop due to the select transistors are increased and may cause serious deterioration in electric characteristics of the memory cell. Therefore, it is preferable that the select transistor is not provided to the source line.

A conventional NAND memory cell array using a hot electron injection scheme disclosed an IEEE document (IEDM-87, P.25.6, 1987 IEEE) may be similar to the present invention shown in FIG. 4 in that there is no select transistor and provided that there are diffusion regions between the storage transistors. However, in the conventional NAND memory cell array, there is a disadvantage in that the operating current and the drain voltage in the programming operation are too high. In addition, in order to pass the high operating current and the high drain voltage, a very high pass gate voltage of 21V needs to be used. Such high voltage and current result in the larger cell and circuit sizes, and may also cause serious reliability problems.

1. A NAND memory cell array comprising:
a select transistor having the one terminal connected to a bit line and a gate terminal applied with a select signal; and
a storage device operated in response to a plurality of word lines, the storage device having the one terminal connected to the other terminal of the select transistor and the other terminal connected to a source line,
wherein the storage device includes at least two storage transistors connected in series between the other terminal of the select transistor and the source line, and
wherein a gate of each storage transistor is connected to each of the plurality of word lines respectively, a bulk region thereof is applied with a bulk bias voltage at the time of writing (programming) data, and a floating gate or a single or multiple charge storage layer is disposed between the gate and the bulk.

2. The NAND memory cell array according to claim 1, wherein the storage device and the select transistor are NMOS transistors, wherein the bulk bias voltage at the time of programming is a negative voltage.

3. The NAND memory cell array according to claim 1, wherein, in a case where the storage device includes the two storage transistors, the storage device includes:
a first storage transistor having the one terminal connected to the other terminal of the select transistor and a gate connected to a first word line; and
a second storage transistor having the one terminal connected to the other terminal of the first storage transistor, the other terminal connected to the source line, and a gate connected to a second word line, and
wherein, in a case where the storage device includes N storage transistors (N is an integer of 3 or more), the storage device includes:
a first storage transistor having the one terminal connected to the other terminal of the select transistor and a gate connected to a first word line;
an (N−1)-th storage transistor having the one terminal connected to the other terminal of an (N−2)-th storage transistor and a gate connected to a (N−1)-th word line; and
an N-th storage transistor having the one terminal connected to the other terminal of the (N−1)-th storage transistor, the other terminal connected to the source line, and a gate connected to an N-th word line.

4. The NAND memory cell array according to claim 1, wherein diffusion regions are provided to the one terminal and the other terminal of the select transistor and the one terminal and the other terminal of the at least two storage transistors.

5. The NAND memory cell array according to claim 1, wherein diffusion regions are provided to the one terminal of the select transistor and the other terminal of the last storage transistor among the at least two serially-connected storage transistors.

6. The NAND memory cell array according to claim 1, wherein diffusion regions are provided to the one terminal and the other terminal of the select transistor and the other terminal of the last storage transistor among the at least two serially-connected storage transistors.

7. A NAND memory cell array comprising a storage device including at least two storage transistors connected in series between a bit line and a source line, wherein, in a case where the storage device includes the two storage transistors, the storage device includes:
a first storage transistor having the one terminal connected to the bit line and a gate applied with a first word signal; and
a second storage transistor having the one terminal connected to the other terminal of the first storage transistor, the other terminal connected to the source line, and a gate connected to a second word line,
wherein, in a case where the storage device includes N storage transistors (N is an integer of 3 or more), the storage device includes:
a first storage transistor having the one terminal connected to the bit line and a gate connected to the first word line;
an (N−1)-th storage transistor having the one terminal connected to the other terminal of an (N−2)-th storage transistor and a gate applied with a (N−1)-th word signal; and
an N-th storage transistor having the one terminal connected to the other terminal of the (N−1)-th storage transistor, the other terminal connected to the source line, and a gate applied with an N-th word signal, and
wherein, when a data is programmed, bulk regions of all the storage transistors are applied with a bulk bias voltage at the time of writing (programming) data, and a floating gate or a single or multiple charge storage dielectric layer is provided between the gate and the bulk.

8. The NAND memory cell array according to claim 7, wherein the storage device and the select transistor are NMOS transistors, wherein the bulk bias voltage at the time of programming is a negative voltage.

9. The NAND memory cell array according to claim 7, wherein diffusion regions are provided to the one terminal of the storage transistor connected to the bit line and the other terminal of the storage transistor connected to the source line.

10. A data processing method for a NAND flash memory having a plurality of memory cell arrays, each memory cell array including a select transistor having the one terminal connected to a bit line and a gate applied with a select signal and at least two storage transistors connected in series between the other terminal of the select transistor and a source line and operated in response to at least two word line signals and a bulk bias voltage applied to a bulk region,
wherein a data is programmed in the NAND flash memory by using hot carriers generated in the bulk region or channel region of the at least two storage transistors by a voltage applied through the bit line, a voltage applied through the source line, and the bulk bias voltage.

11. The data processing method according to claim 10, wherein the select transistor and the at least two storage transistors are NMOS transistors,
wherein the data is programmed in the each storage transistor according to the following conditions,
wherein a voltage level of the bit line is in a range of 1V to 6V,
wherein a voltage level of the select signal is in a range of 3V to 12V,
wherein a voltage level of a word line signal applied to the storage transistor in which the data is to be programmed among the at least two word line signals is in a range of −3V to 10V,
wherein, among the remaining storage transistors, a voltage level of a word line signal applied to a storage transistor between the select transistor and the storage transistor in which the data is to be stored is in a range of 3V to 12V, and a voltage level of a word line signal applied to a storage transistor between the source line and the storage transistor in which the data is to be stored is in a range of 2V to 12V,
wherein a voltage level of the source line is in a range of 0V to 2V, and
wherein the bulk bias voltage is in a range of −4V to 0V.

12. A data processing method for a NAND flash memory having a plurality of memory cell arrays, each memory cell array including a select transistor having the one terminal connected to a bit line and a gate applied with a select signal and at least two storage transistors connected in series between the other terminal of the select transistor and a source line and operated in response to at least two word line signals and a bulk bias voltage applied to a bulk region,
wherein a data is programmed in the NAND flash memory by using hot carriers generated in the bulk region or channel region of the at least two storage transistors by a voltage applied through the bit line, a voltage applied through the source line, and the bulk bias voltage, and
wherein the data is programmed by changing a voltage level of a word line signal applied to a gate of a storage transistor in which the data is to be programmed among the at least two storage transistors.

13. The data processing method according to claim 12, wherein the voltage level of the word line signal applied to the storage transistor in which the data is to be programmed is changed stepwise or linearly from an initial voltage level to a final voltage level.

14. The data processing method according to claim 12, wherein at least one of the voltage levels of the select signal and the word line signals applied to the storage transistors in which the data is not to be programmed is changed from an initial voltage level to a final voltage level when the data is programmed.

15. The data processing method according to claim 12, wherein the select transistor and the at least two storage transistors are NMOS transistors,
wherein the data is programmed in the storage transistor according to the following conditions,
wherein a voltage level of the bit line is in a range of 1V to 6V,
wherein a voltage level of the select signal is in a range of 3V to 12V,
wherein a voltage level of a word line signal applied to the storage transistor in which the data is to be programmed among the at least two word lines signal is in a range of −3V to 10V,
wherein, among the remaining storage transistors, a voltage level of a word line signal applied to a storage transistor between the select transistor and the storage transistor in which the data is to be stored is in a range of 3V to 12V, and a voltage level of a word line signal applied to a storage transistor between the source line and the storage transistor in which the data is to be stored is in a range of 2V to 12V,
wherein a voltage level of the source line is in a range of 0V to 2V, and
wherein the bulk bias voltage is in a range of −4V to 0V.

16. The data processing method according to claim 13,
wherein the storage transistor is an NMOS transistor,
wherein the initial voltage level is in a range of −3V to 3V, and
wherein the final voltage level is in a range of 0V to 12V.

17. The data processing method according to claim 12,
wherein the select transistor and the at least two storage transistors are NMOS transistors,
wherein a data programmed in the storage transistor is erased according the following conditions,
wherein the bit line, the select signal, and the source line are in a floating state,
wherein voltage levels of all word line signals applied to the storage transistors from which the data is to be erased is in a range of −12 to 0V, and
wherein the bulk bias voltage is in a range of Vcc (a power voltage of the NAND flash memory) to 20V.

18. The data processing method according to claim 17, wherein the voltage levels of all the word lines are gradually decreased from a higher voltage to a lower voltage and/or the bulk bias voltage is gradually increased from a lower voltage to a higher voltage during the data erasing operation.

19. The data processing method according to claim 12,
wherein the select transistor and the at least two storage transistors are NMOS transistors,
wherein a data programmed in the storage transistor is read according to the following conditions,
wherein a voltage level of the bit line is in a range of 0.4V to 2V,
wherein a voltage level of the select signal is in a range of 1V to 7V,
wherein a voltage level of a word line signal applied to the storage transistor from which the data is to be read is a range of 0V to 5V,
wherein voltage levels of word line signals applied to the remaining storage transistors are in a range of 1V to 7V,
wherein a voltage level of the source line is 0V, and
wherein the bulk bias voltage is in a range of −3V to 0V.

20. A data processing method for a NAND flash memory having a plurality of memory cell arrays, each memory cell array including at least two storage transistors connected in series between a bit line and a source line and operated in response to at least two word line signals and a bulk bias voltage applied to a bulk region,
wherein data is programmed in the NAND flash memory by using hot carriers generated in the bulk region or channel region of the at least two storage transistors by a voltage applied through the bit line, a voltage applied through the source line, and the bulk bias voltage, and
wherein the data is programmed by changing a voltage level of a word line signal applied to a gate of a storage transistor in which the data is to be stored among at least the two storage transistors.

21. The data processing method according to claim 20, wherein at least one of the voltage level of the word line signals applied to the storage transistors in which the data is not to be programmed is changed from an initial voltage level to a final voltage level during the data is programmed.

22. The data processing method according to claim 20,
wherein at least the two storage transistors are NMOS transistors,
wherein a data is programmed in the NAND flash memory according to the following conditions,
wherein a voltage level of the bit line is in a range of 1V to 6V,
wherein a voltage level of a word line signal applied to the storage transistor in which the data is to be programmed among the at least two word line signals is in a range of −3V to 10V,
wherein, voltage levels of word line signals applied to storage transistors other than the storage transistor in which the data is to be stored are in a range of 2V to 12V,
wherein a voltage level of the source line is in a range of 0V to 2V, and
wherein the bulk bias voltage is in a range of −4V to 0V.

23. The data processing method according to claim 20,
wherein at least the two storage transistors are NMOS transistors,
wherein a data is programmed in the at least two storage transistors according to the following conditions,
wherein, among at least the two word line signals, the voltage level of the word line signal applied to the storage transistor in which the data is to be stored is changed from an initial voltage level to a final voltage level during the data programming operation, and
wherein the initial voltage level is in a range of −3V to 3V, and the final voltage level is in a range of 0V to 12V.

24. The data processing method according to claim 20,
wherein at least the two storage transistors are NMOS transistors,
wherein data programmed in the at least two storage transistors are erased according to the following conditions,
wherein the bit line and the source line are in a floating state,
wherein voltage levels of all word line signals applied to the at least two storage transistors are in a range of −12V to 0V, and
wherein the bulk bias voltage is in a range of Vcc to 20V.

25. The data processing method according to claim 24,
wherein the voltage levels of all the word line signals are gradually decreased from a higher voltage to a lower voltage and/or the bulk bias voltage is gradually increased from a lower voltage to a higher voltage during the data erasing operation.
